(19) United States
(12) Patent Application Publication
(10) Pub. No.: US 2026/0230020 A1
(43) Pub. Date: Aug. 6, 2026

(54) DRIVE CONTROL DEVICE

(71) Applicant: Astemo, Ltd., Chiyoda-ku, Tokyo (JP)

(72) Inventors: Akira lSHII, Hitachinaka-shi, Ibaraki (JP); Tomio SAKASHITA, Hitachinaka-shi, Ibaraki (JP); Susumu KANEKO, Hitachinaka-shi, Ibaraki (JP)

(73) Assignee: Astemo, Ltd., Chiyoda-ku, Tokyo (JP)

(21) Appl. No.: 19/155,547

(22) PCT Filed: Feb. 15, 2024
(86) PCT No.: PCT/JP2024/005127

§ 371 Date: Aug. 11, 2025

(30) Foreign Application Priority Data
Mar. 2, 2023 (JP) 2023-031703

(51) Int. Cl. H02P 23/00

(52) U.S. Cl. CPC H02P 23/00

(57) ABSTRACT

In a first drive control device (DA1) as a drive control device according to the present invention, a center (G3) of a third microcomputer (MP13) is located at one side with respect to a virtual line (VL) connecting a center (G1) of a first microcomputer (MP11) and a center (G2) of a second microcomputer (MP12). Further, at least a part of the third microcomputer (MP13) overlaps at least one of the first microcomputer (MP11) and the second microcomputer (MP12) when viewed from a direction orthogonal to the virtual line (VL) in a horizontal direction of a circuit board (1).

### TECHNICAL FIELD

The present invention relates to a drive control device.

### BACKGROUND ART

As a related art drive control device, for instance, a drive control device described in the following Patent Document 1 has been known.

When describing an outline of this drive control device briefly, the drive control device is a so-called redundant drive control device that has three CPUs (microcomputers) and can drive and control motors of two systems using two of the three CPUs.

### CITATION LIST

### Patent Document

Patent Document 1: Japanese Unexamined Patent Application Publication No. 2004-080939

### SUMMARY OF THE INVENTION

### Technical Problem

However, in the related art drive control device, arrangement of the three CPUs is not taken into consideration at all. For this reason, for instance, as illustrated in the Patent Document 1, when the three CPUs are arranged parallel so that their centers are located on the same straight line, a wiring distance between the CPUs arranged at both end sides becomes longer than a wiring distance between the CPU arranged in the middle and each of the CPUs arranged at both end sides. Therefore, there is room for improvement in that noise resistance of the drive control device decreases.

The present invention was made in view of the above technical problem of the related art drive control device. An object of the present invention is therefore to provide a drive control device that is capable of suppressing the decrease in the noise resistance.

### Solution to Problem

According to one aspect of the present invention, a third microcomputer is arranged such that a center of the third microcomputer is located at one side with respect to a virtual line connecting a center of a first microcomputer and a center of a second microcomputer, and such that at least a part of the third microcomputer overlaps at least one of the first microcomputer and the second microcomputer when viewed from a direction orthogonal to the virtual line in a horizontal direction of a circuit board.

### Effects of Invention

According to the present invention, it is possible to suppress the decrease in the noise resistance.

### BRIEF DESCRIPTION OF THE DRAWINGS

FIG. 1 is a block diagram showing a system configuration of a drive control device according to the present invention.

FIG. 2 is a plan view of a circuit board according to a first embodiment of the drive control device according to the present invention.

FIG. 3 is a schematic diagram of the circuit board showing an essential part of the first embodiment of the present invention.

FIGS. 4A to 4D are other examples of the first embodiment of the present invention, and showing schematic diagrams of variations in arrangement (layout) of microcomputers on the circuit board.

FIG. 5 is a schematic diagram of a circuit board according to a modified example of the first embodiment of the present invention.

FIG. 6 is a schematic diagram of a circuit board showing an essential part of a second embodiment of the present invention.

FIG. 7 is a schematic diagram of a circuit board showing an essential part of a third embodiment of the present invention.

FIGS. 8A and 8B are schematic diagrams of a circuit board showing an essential part of a fourth embodiment of the present invention. FIG. 8A is a plan view. FIG. 8B is a sectional view taken along a line A-A of FIG. 8A.

FIGS. 9A and 9B are schematic diagrams of a circuit board according to a modified example of the fourth embodiment of the present invention FIG. 9A is a plan view. FIG. 9B is a sectional view taken along a line B-B of FIG. 9A.

### EMBODIMENTS FOR CARRYING OUT THE INVENTION

Embodiments of a drive control device according to the present invention will be described below with reference to the drawings. In the following embodiments, examples in which the drive control device according to the present invention is applied to an ECU for a steering device of a vehicle will be described.

### First Embodiment

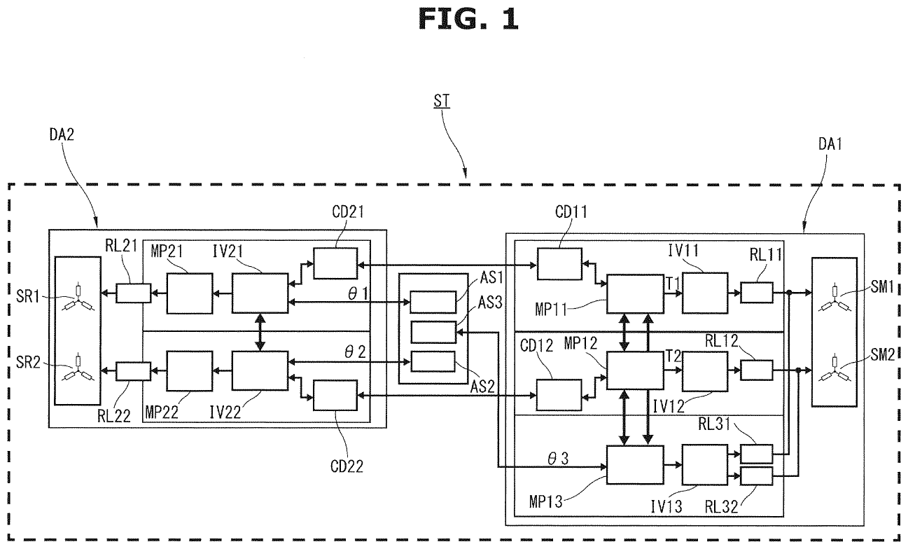

FIG. 1 illustrates a block diagram showing a system configuration of a steering device to which a drive control device (a first drive control device DA1 described later) according to the present embodiment is applied.

As illustrated in FIG. 1, a steering device ST is configured by a so-called steer-by-wire system in which a steering wheel (not shown) and steered wheels (not shown) are not mechanically connected. More specifically, the steering device ST is provided with a triplex redundant system, and includes three steering angle sensors of first, second and third steering angle sensors AS1, AS2 and AS3, the first drive control device DA1 that generates a steering force on the steered wheels (not shown) on the basis of a steering angle etc. input to each of the steering angle sensors AS1, AS2 and AS3, and a second drive control device DA2 that generates a reaction force, which acts as a steering resistance, to the steering wheel (not shown) side, on the basis of the steering angle etc. input to each of the steering angle sensors AS1, AS2 and AS3.

The first drive control device DA1 includes first and second steering motors SM1 and SM2, which are two-system steering motors, and three microprocessors (microcomputers) of first, second and third microcomputers MP11, MP12 and MP13 and first, second and third inverters IV11, IV12 and IV13, which constitute a triplex control system.

Of the first, second and third microcomputers MP11, MP12 and MP13 constituting the triplex control system, the first and second microcomputers MP11 and MP12 each constitute a main system, whereas the third microcomputer MP13 constitutes a backup system. That is, the first microcomputer MP11 drives and controls the first steering motor SM1 via the first inverter IV11. Likewise, the second microcomputer MP12 drives and controls the second steering motor SM2 via the second inverter IV12. The third microcomputer MP13 drives and controls the first steering motor SM1 or the second steering motor SM2 via the third inverter IV13 when the first microcomputer MP11 or the second microcomputer MP12 fails.

The first microcomputer MP11 inputs, via a first CAN driver CD11, a first steering angle θ1 detected by the first steering angle sensor AS1. Likewise, the second microcomputer MP12 inputs, via a second CAN driver CD12, a second steering angle θ2 detected by the second steering angle sensor AS2. On the other hand, the third microcomputer MP13 directly inputs a third steering angle θ3 detected by the third steering angle sensor AS3.

The first inverter IV11 is connected to the first steering motor SM1 via a first relay RL11. Likewise, the second inverter IV12 is connected to the second steering motor SM2 via a second relay RL12. On the other hand, the third inverter IV13 is connected to the first steering motor SM1 via a first third relay RL31, and also is connected to the second steering motor SM2 via a second third relay RL32.

The second drive control device DA2 includes first and second reaction force motors SR1 and SR2, which are two-system reaction force motors, and two microprocessors (microcomputers) of first and second microcomputers MP21 and MP22 and first and second inverters IV21 and IV22, which constitute a dual control system.

The first microcomputer MP21 drives and controls the first reaction force motor SR1 via the first inverter IV21. The first inverter IV21 is connected to the first reaction force motor SR1 via a first relay RL21. Likewise, the second microcomputer MP22 drives and controls the second reaction force motor SR2 via the second inverter IV22. The second inverter IV22 is connected to the second reaction force motor SR2 via a second relay RL22.

The first microcomputer MP21 inputs, via a first CAN driver CD21, the first steering angle θ1 detected by the first steering angle sensor AS1. Likewise, the second microcomputer MP22 inputs, via a second CAN driver CD22, the second steering angle θ2 detected by the second steering angle sensor AS2. Here, the first CAN driver CD21 of the second drive control device DA2 can mutually communicate with the first CAN driver CD11 of the first drive control device DA1, and the second CAN driver CD22 of the second drive control device DA2 can mutually communicate with the second CAN driver CD12 of the first drive control device DA1.

### Configuration of Drive Control Device

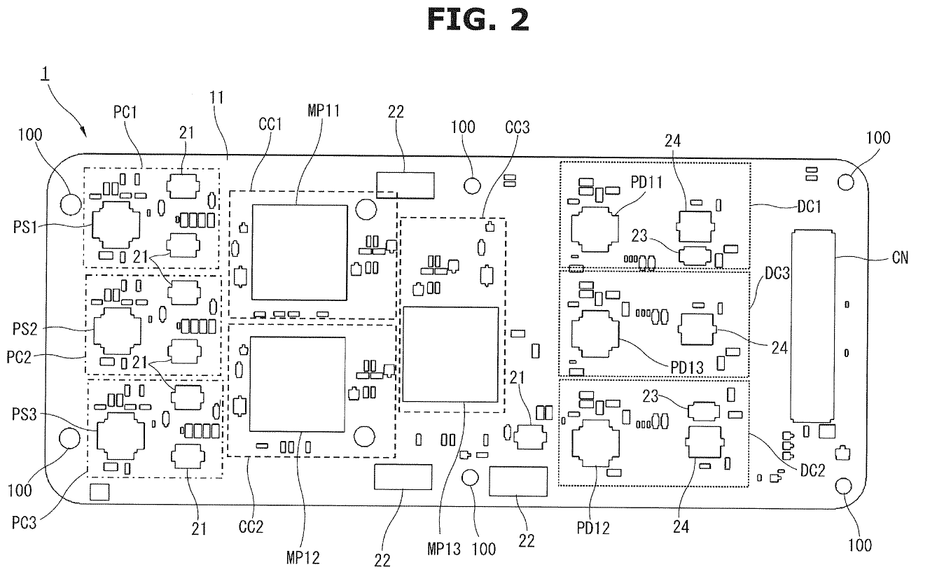

FIG. 2 illustrates a plan view of a circuit board constituting the first drive control device DA1.

The first drive control device DAl is configured by accommodating a substantially rectangular circuit board 1 shown in FIG. 2 inside a housing (not shown). The circuit board 1 is fixed to the housing (not shown) inside the housing (not shown) with fastening members (e.g. screws etc.) that penetrate six mounting holes 100 arranged at an outer peripheral edge portion of the circuit board 1. Here, the first drive control device DA1 can be configured by a single circuit board or a plurality of circuit boards. In the present embodiment, the first drive control device DA1 is configured by a plurality of circuit boards, and the circuit board 1 illustrated in FIG. 2 is one of the plurality of circuit boards constituting the first drive control device DA1. The circuit board 1 is connected to the other circuit board(s) (not shown) via a harness (not shown) that is inserted into a connector CN described later.

More specifically, the circuit board 1 has a first mounting surface 11 provided on a surface of the circuit board 1 as shown in FIG. 2. On this first mounting surface 11, electronic circuits (patterns) (not shown) that flow from a left side to a right side in FIG. 2 are formed. Further, the three microprocessors of the first, second and third microcomputers MP11, MP12 and MP13, three power supply elements (power supply ICs) of first, second and third power supply elements PS1, PS2 and PS3, and three pre-drivers of first, second and third pre-drivers PD11, PD12 and PD13, are mainly mounted on the first mounting surface 11. Also, on the first mounting surface 11 of the circuit board 1, the connector CN, which is a Board-to-Board connector for connection to the other circuit board(s) (not shown), is provided at an end portion (a right end portion in FIG. 2) in a longitudinal direction of the first mounting surface 11. Furthermore, a plurality of coils 21, a plurality of inspection connectors 22, a plurality of diodes 23, a plurality of electrolytic capacitors 24, etc. are mounted on the first mounting surface 11 of the circuit board 1.

The first, second and third microcomputers MP11, MP12 and MP13 constitute the triplex control system, the first and second microcomputers MP11 and MP12 constitute the main systems, and the third microcomputer MP13 constitutes the backup system. Therefore, when the first and second microcomputers MP11 and MP12 are operating normally, the first and second microcomputers MP11 and MP12 calculate first and second driving torques T1 and T2 on the basis of the first and second steering angles θ1 and θ2 detected by the first and second steering angle sensors AS1 and AS2 (see FIG. 1) respectively. On the other hand, if either the first microcomputer MP11 or the second microcomputer MP12 fails, as an alternative to the first microcomputer MP11 or the second microcomputer MP12 which is in a failed state, the third microcomputer MP13 calculates the first or second driving torque T1 or T2 on the basis of the first or second steering angle θ1 or θ2.

On the circuit board 1, the first microcomputer MP11 including peripheral electronic components such as chip capacitors and chip resistors constitute a first central processing circuit CC1. Likewise, on the circuit board 1, the second microcomputer MP12 including peripheral electronic components such as chip capacitors and chip resistors constitute a second central processing circuit CC2. Also, on the circuit board 1, the third microcomputer MP13 including peripheral electronic components such as chip capacitors and chip resistors constitute a third central processing circuit CC3.

The first power supply element PS1 supplies driving power to the first microcomputer MP11. The first power supply element PS1 including peripheral electronic components such as chip capacitors and chip resistors constitute a first power supply circuit PC1. Likewise, the second power supply element PS2 supplies driving power to the second microcomputer MP12. The second power supply element PS2 including peripheral electronic components such as chip capacitors and chip resistors constitute a second power supply circuit PC2. Also, the third power supply element PS3 supplies driving power to the third microcomputer MP13. The third power supply element PS3 including peripheral electronic components such as chip capacitors and chip resistors constitute a third power supply circuit PC3.

The first pre-driver PD11 drives and controls the first steering motor SM1 on the basis of the first driving torque T1 calculated by the first microcomputer MP11. The first pre-driver PD11 including peripheral electronic components such as chip capacitors and chip resistors constitute a first input circuit DC1. Likewise, the second pre-driver PD12 drives and controls the second steering motor SM2 on the basis of the second driving torque T2 calculated by the second microcomputer MP12. The second pre-driver PD12 including peripheral electronic components such as chip capacitors and chip resistors constitute a second input circuit DC2. Also, the third pre-driver PD13 drives and controls the first steering motor SM1 or the second steering motor SM2 on the basis of the first driving torque T1 or the second driving torque T2 calculated by the third microcomputer MP13. The third pre-driver PD13 including peripheral electronic components such as chip capacitors and chip resistors constitute a third input circuit DC3.

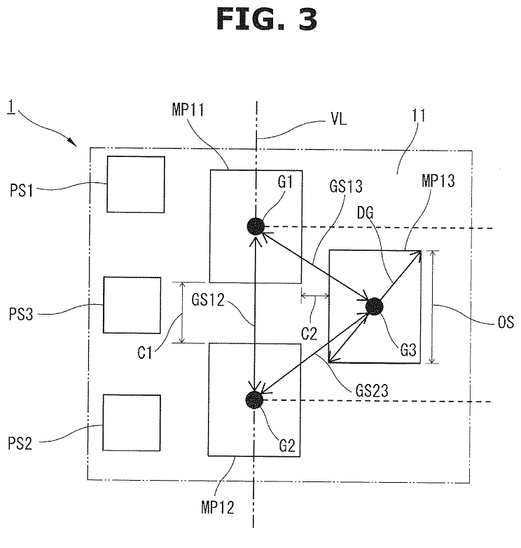

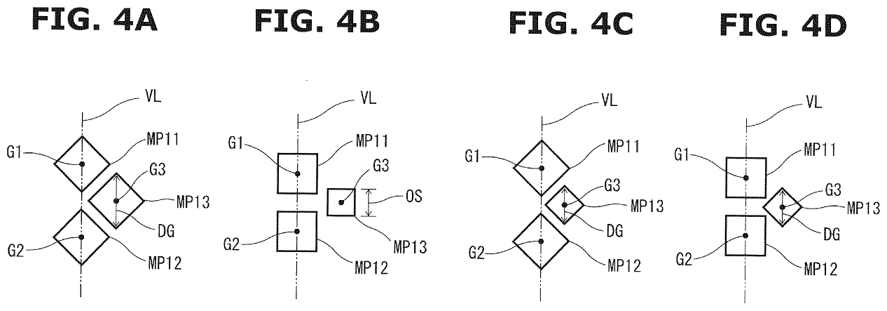

FIG. 3 is a schematic diagram showing a positional relationship (layout) between the first, second and third microcomputers MP11, MP12 and MP13 and the first, second and third power supply elements PS1, PS2 and PS3 on the first mounting surface 11 of the circuit board 1, which is a distinctive configuration according to the present embodiment. FIGS. 4A to 4D are schematic diagrams showing modified examples of arrangement configuration (layout) of the first, second and third microcomputers MP11, MP12 and MP13 on the first mounting surface 11 of the circuit board 1.

As illustrated in FIG. 3, on the circuit board 1, of the first, second and third microcomputers MP11, MP12 and MP13, the first microcomputer MP11 and the second microcomputer MP12 constituting the main systems are arranged in a so-called mirroring state so as to face each other in a direction (an up-and-down direction of FIG. 3) orthogonal to the longitudinal direction of the circuit board 1. Furthermore, the first microcomputer MP11 and the second microcomputer MP12 are arranged close to each other with a distance C1 that is shorter than one side OS or a diagonal line DG of an outline of the third microcomputer MP13 in a plan view of the circuit board 1.

Also, on the circuit board 1, of the first, second and third microcomputers MP11, MP12 and MP13, the third microcomputer MP13 constituting the backup system is arranged at a downstream side with respect to the first and second microcomputers MP11 and MP12, i.e. at a pre-driver (the first, second and third pre-drivers PD11, PD12 and PD13) side with respect to a virtual line VL connecting a center G1 of the first microcomputer MP11 and a center G2 of the second microcomputer MP12. Furthermore, the third microcomputer MP13 is arranged such that a part of the third microcomputer MP13 overlaps at least one of the first microcomputer MP11 and the second microcomputer MP12 when viewed froma direction orthogonal to the virtual line VL in a horizontal direction of the circuit board 1.

Here, as illustrated in FIG. 3, it is desirable that a center G3 of the third microcomputer MP13 is located between the center Gl of the first microcomputer MP11 and the center G2 of the second microcomputer MP12 (i.e. within GS12) in a plan view of the circuit board 1. It is more desirable that the third microcomputer MP13 is arranged such that the center G3 of the third microcomputer MP13 is equidistant from the centers G1 and G2 of the first and second microcomputers MP11 and MP12, i.e. a distance GS13 between the first microcomputer MP11 and the third microcomputer MP13 and a distance GS23 between the second microcomputer MP12 and the third microcomputer MP13 are equal to each other.

It is noted that the above-mentioned “the third microcomputer MP13 is arranged such that a part of the third microcomputer MP13 overlaps at least one of the first microcomputer MP11 and the second microcomputer MP12 when viewed from a direction orthogonal to the virtual line VL in a horizontal direction of the circuit board 1” includes not only an arrangement in which, as shown in FIG. 3, one sides OS of the first, second and third microcomputers MP11, MP12 and MP13 are parallel to or perpendicular to the virtual line VL, but also an arrangement in which, for instance, as shown in FIG. 4A, diagonal lines DG of the first, second and third microcomputers MP11, MP12 and MP13 are parallel to the virtual line VL.

Furthermore, since the third microcomputer MP13 constitutes the backup system, for instance, as depicted in FIGS. 4B and 4C, the third microcomputer MP13 could be formed differently in size from the first and second microcomputers MP11 and MP12 that are arranged in a mirroring state and that constitute the main systems. In addition, in this case, for instance, as seen in FIG. 4D, the first, second and third microcomputers MP11, MP12 and MP13 may be arranged so as to have different orientations such that only one sides OS of the first and second microcomputers MP11 and MP12 are parallel to or perpendicular to the virtual line VL, and only a diagonal line DG of the third microcomputer MP13 is parallel to the virtual line VL.

Moreover, in the present embodiment, on the circuit board 1, the third microcomputer MP13 is arranged close to the first and second microcomputers MP11 and MP12 with a distance C2 that is shorter than the distance C1 between the first and second microcomputers MP11 and MP12.

Additionally, on the circuit board 1, the first, second and third power supply elements PS1, PS2 and PS3 are arranged at an upstream side with respect to the first, second and third microcomputers MP11, MP12 and MP13, i.e. at an opposite side to the pre-driver (the first, second and third pre-drivers PD11, PD12 and PD13) with respect to the virtual line VL. Here, in the present embodiment, the first, second and third power supply elements PS1, PS2 and PS3 are arranged parallel at substantially regular intervals along an up-and-down direction of the circuit board 1, i.e. a direction parallel to the virtual line VL. Also, the first, second and third power supply elements PS1, PS2 and PS3 are arranged such that the first power supply element PS1 and the second power supply element PS2 are located at both end sides in a mirroring state, and the third power supply element PS3 is located between the first power supply element PS1 and the second power supply element PS2.

### Working and Effect of the Present Embodiment

In the related art drive control device, the arrangement (layout) of the first, second and third microcomputers, which are the three CPUs, is not taken into consideration at all. For this reason, for instance, as illustrated in the Patent Document 1, when the first, second and third microcomputers are arranged parallel so that their centers are located on the same straight line, a wiring distance between the first and second microcomputers arranged at both end sides becomes longer than a wiring distance between the third microcomputer arranged in the middle and each of the first and second microcomputers arranged at both end sides. Therefore, there is room for improvement in that noise resistance of the drive control device decreases.

In contrast to this, the first drive control device DA1 according to the present embodiment is a drive control device comprising at least three drive systems each supplying driving power to a winding of an electric motor (the first and second steering motors SM1 and SM2). A first drive system, a second drive system, and a third drive system, which constitute the three drive systems, include, on a circuit board 1, a first microcomputer MP11, a second microcomputer MP12, and a third microcomputer MP13 respectively, which are rectangular in shape in a plan view of the circuit board 1. The first drive system is driven and controlled by the first microcomputer MP11, the second drive system is driven and controlled by the second microcomputer MP12, and the third drive system is driven and controlled by the third microcomputer MP13. The first microcomputer MP11, and the second microcomputer MP12 are arranged closer than a dimension of one side OS or a diagonal line DG of an outline of the third microcomputer MP13 in the plan view of the circuit board 1. The third microcomputer MP13 is arranged such that a center G3 of the third microcomputer MP13 is located at one side with respect to a virtual line VL connecting a center Gl of the first microcomputer MP11 and a center G2 of the second microcomputer MP12, and at least a part of the third microcomputer MP13 overlaps at least one of the first microcomputer MP11 and the second microcomputer MP12 when viewed froma direction orthogonal to the virtual line VL in a horizontal direction of the circuit board 1.

As described above, in the first drive control device DA1 according to the present embodiment, the third microcomputer MP13 is arranged such that the center G3 of the third microcomputer MP13 is located at one side with respect to the virtual line VL connecting the center G1 of the first microcomputer MP11 and the center G2 of the second microcomputer MP12, and such that at least a part of the third microcomputer MP13 overlaps at least one of the first microcomputer MP11 and the second microcomputer MP12 when viewed froma direction orthogonal to the virtual line VL in a horizontal direction of the circuit board 1. With this arrangement, a wiring distance between the first microcomputer MP11 and the second microcomputer MP12, a wiring distance between the first microcomputer MP11 and the third microcomputer MP13, and a wiring distance between the second microcomputer MP12 and the third microcomputer MP13 can be each shortened. In other words, in addition to a wiring distance between the first and second microcomputers MP11 and MP12 and the third microcomputer MP13, a wiring distance between the first microcomputer MP11 and the second microcomputer MP12 can also be shortened. It is therefore possible to suppress decrease in noise resistance of the first drive control device DA1.

Further, in the present embodiment, the first drive system and the second drive system are main systems that mainly drive and control the electric motors (the first and second steering motors SM1 and SM2), and the third drive system is a backup system that functions as an alternative to the first drive system or the second drive system when the first drive system or the second drive system fails.

As described above, according to the present embodiment, even when either the first drive system or the second drive system fails, the third drive system as the backup system substitutes for the failed one of the first drive system or the second drive system. Therefore, it is possible to maintain the redundant control that drives the two-system electric motors (the first and second steering motors SM1 and SM2).

Furthermore, in the present embodiment, the third microcomputer MP13 is arranged such that the center G3 of the third microcomputer MP13 is located between the center G1 of the first microcomputer MP11 and the center G2 of the second microcomputer MP12 when viewed from the direction orthogonal to the virtual line VL in the horizontal direction of the circuit board 1.

According to the present invention, the third microcomputer MP13 is arranged such that the center G3 of the third microcomputer MP13 is located between the center G1 of the first microcomputer MP11 and the center G2 of the second microcomputer MP12. This can reduce imbalance in distances between the first, second and third microcomputers MP11, MP12 and MP13, and suppress functional difference caused by the imbalance.

Moreover, especially in the present embodiment, the first microcomputer MP11, the second microcomputer MP12 and the third microcomputer MP13 are arranged at equal distances from each other.

As described above, according to the present embodiment, the first microcomputer MP11, the second microcomputer MP12 and the third microcomputer MP13 are arranged at equal distances from each other. Therefore, each of distances between the first, second and third microcomputers MP11, MP12 and MP13 is optimized, thereby suppressing functional difference caused by the imbalance in distances between the first, second and third microcomputers MP11, MP12 and MP13.

### Modified Example

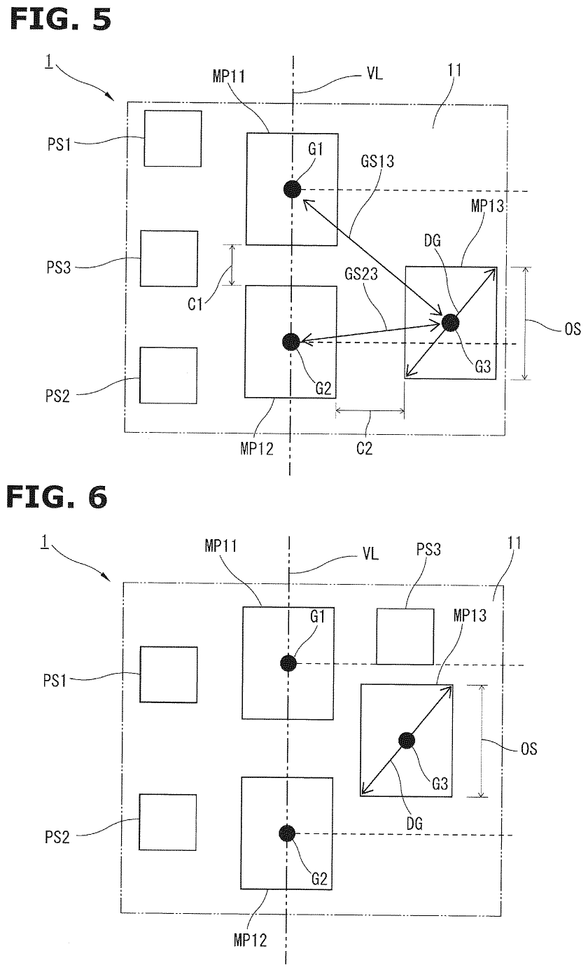

FIG. 5 is a modified example of the first embodiment of the drive control device according to the present invention, and shows a positional relationship (layout) between the first, second and third microcomputers MP11, MP12 and MP13 and the first, second and third power supply elements PS1, PS2 and PS3 on the first mounting surface 11 of the circuit board 1.

As illustrated in FIG. 5, in the first drive control device DA1 according to the present modified example, the third microcomputer MP13 is located apart from the first microcomputer MP11 and the second microcomputer MP12 with a distance that is greater than a distance (a distance C1) between the first microcomputer MP11 and the second microcomputer MP12 and that is smaller than a dimension of one side OS or a diagonal line DG of an outline of the third microcomputer MP13.

As described above, in the present modified example, the third microcomputer MP13 is located apart from the first and second microcomputers MP11 and MP12 with a distance (a distance c2) that is greater than the distance (the distance C1) between the first and second microcomputers MP11 and MP12. It is thus possible to suppress thermal influence of the third microcomputer MP13 on the first and second microcomputers MP11 and MP12.

### Second Embodiment

FIG. 6 illustrates a second embodiment of the drive control device according to the present invention. In the present embodiment, arrangement of the third power supply element PS3 is changed from the first embodiment, but the other configurations are the same as those of the first embodiment. Therefore, the same configurations are denoted by the same reference sign, and their detailed descriptions are omitted here.

### Configuration of Drive Control Device

FIG. 6 is a schematic diagram showing a positional relationship (layout) between the first, second and third microcomputers MP11, MP12 and MP13 and the first, second and third power supply elements PS1, PS2 and PS3 on the first mounting surface 11 of the circuit board 1, which is a distinctive configuration according to the present embodiment.

As illustrated in FIG. 6, in the first drive control device DA1 according to the present embodiment, the third power supply element PS3 is located at an upper side of the third microcomputer MP13, i.e. arranged along a direction substantially parallel to the virtual line VL, parallel to the third microcomputer MP13, in a plan view of the first mounting surface 11 of the circuit board 1. In other words, in the present embodiment, third power supply element PS3 is arranged at a downstream side with respect to the first and second microcomputers MP11 and MP12, i.e. at a pre-driver (the first, second and third pre-drivers PD11, PD12 and PD13) side with respect to the virtual line VL.

### Working and Effect of the Present Embodiment

As described above, in the first drive control device DA1 according to the present embodiment, the first drive system includes a first power supply element PS1 that supplies power to the first microcomputer MP11, and a first pre-driver PD11 that drives the electric motor (the first and second steering motors SM1 and SM2) based on a control signal from the first microcomputer MP11. The second drive system includes a second power supply element PS2 that supplies power to the second microcomputer MP12, and a second pre-driver PD12 that drives the electric motor (the first and second steering motors SM1 and SM2) based on a control signal from the second microcomputer MP12. The third drive system includes a third power supply element PS3 that supplies power to the third microcomputer MP13, and a third pre-driver PD13 that drives the electric motor (the first and second steering motors SM1 and SM2) based on a control signal from the third microcomputer MP13. The electric motor (the first and second steering motors SM1 and SM2) is driven by each of the pre-drivers PD11, PD12, PD13, based on the control signal from the first microcomputer MP11, the second microcomputer MP12, or the third microcomputer MP13. The first pre-driver PD11, the second pre-driver PD12, and the third pre-driver PD13 are arranged at an opposite side to the first microcomputer MP11 and the second microcomputer MP12 with respect to the third microcomputer MP13. The first power supply element PS1, and the second power supply element PS2 are arranged at an opposite side to the pre-drivers PD11, PD12, PD13 with respect to the first microcomputer MP11 and the second microcomputer MP12. The third microcomputer MP13, and the third power supply element PS3 are arranged along a parallel direction of the first microcomputer MP11 and the second microcomputer MP12.

As described above, in the present embodiment, the third microcomputer MP13 and the third power supply element PS3 are arranged along the parallel direction of the first microcomputer MP11 and the second microcomputer MP12. Therefore, there is no risk that the wiring (a conductor) connecting the third power supply element PS3 and the third microcomputer MP13 will straddle the first and second microcomputers MP11 and MP12. It is thus possible to suppress influence of noise that occurs when power supply from the third power supply element PS3 to the third microcomputer MP13 is done while straddling the first and second microcomputers MP11 and MP12.

Furthermore, in the present embodiment, the first power supply element PS1, and the second power supply element PS2 are arranged at an opposite side to the pre-drivers (the first, second and third pre-drivers PD11, PD12 and PD13) with respect to the first microcomputer MP11 and the second microcomputer MP12. Also, the third microcomputer MP13, and the third power supply element PS3 are arranged at a pre-driver (the first, second and third pre-drivers PD11, PD12 and PD13) side with respect to the first microcomputer MP11 and the second microcomputer MP12. Therefore, the third power supply element PS3 is arranged apart from the first power supply element PS1 and the second power supply element PS2. It is thus possible to suppress thermal influence of the third power supply element PS3 on the first power supply element PS1 and the second power supply element PS2. Therefore, the third power supply element PS3 is located apart from the first and second power supply elements PS1 and PS2, thereby suppressing thermal influence of the third power supply element PS3 on the first and second power supply elements PS1 and PS2.

In addition, in the present embodiment, the third power supply element PS3 and the third microcomputer MP13 are located at the pre-driver (the first, second and third pre-drivers PD11, PD12 and PD13) side with respect to the first and second microcomputers MP11 and MP12.

Therefore, even if the third microcomputer MP13 and the third power supply element PS3 are not arranged in the parallel direction of the first microcomputer MP11 and the second microcomputer MP12, there is no risk that the wiring (a conductor) connecting the third power supply element PS3 and the third microcomputer MP13 will straddle the first and second microcomputers MP11 and MP12. It is thus possible to suppress influence of noise that occurs when power supply from the third power supply element PS3 to the third microcomputer MP13 is done while straddling the first and second microcomputers MP11 and MP12.

In other words, by arranging the third power supply element PS3 and the third microcomputer MP13 at the pre-driver (the first, second and third pre-drivers PD11, PD12 and PD13) side with respect to the first and second microcomputers MP11 and MP12, even if the third microcomputer MP13 and the third power supply element PS3 are not arranged along the parallel direction of the first microcomputer MP11 and the second microcomputer MP12, it is possible to suppress influence of noise that occurs when power supply from the third power supply element PS3 to the third microcomputer MP13 is done while straddling the first and second microcomputers MP11 and MP12.

### Third Embodiment

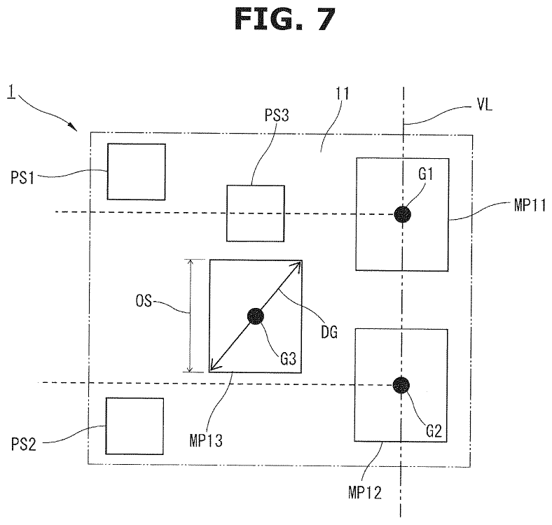

FIG. 7 illustrates a third embodiment of the drive control device according to the present invention. In the present embodiment, arrangement of the third power supply element PS3 and the third microcomputer MP13 of the first embodiment is changed, but the other configurations are the same as those of the first embodiment. Therefore, the same configurations are denoted by the same reference sign, and their detailed descriptions are omitted here.

### Configuration of Drive Control Device

FIG. 7 is a schematic diagram showing a positional relationship (layout) between the first, second and third microcomputers MP11, MP12 and MP13 and the first, second and third power supply elements PS1, PS2 and PS3 on the first mounting surface 11 of the circuit board 1, which is a distinctive configuration according to the present embodiment.

As illustrated in FIG. 7, in the first drive control device DA1 according to the present embodiment, on the first mounting surface 11 of the circuit board 1, the third microcomputer MP13 is arranged at an upstream side with respect to the first and second microcomputers MP11 and MP12, i.e. at the first and second power supply elements PS1 and PS2 side with respect to the virtual line VL. Further, on the first mounting surface 11, the third power supply element PS3 is not located between the first and second power supply elements PS1 and PS2, but is located at an upper side of the third microcomputer MP13, i.e. arranged along a direction substantially parallel to the virtual line VL, parallel to the third microcomputer MP13.

### Working and Effect of the Present Embodiment

As described above, in the first drive control device DA1 according to the present embodiment, the third microcomputer MP13 and the third power supply element PS3 are arranged along the parallel direction of the first microcomputer MP11 and the second microcomputer MP12.

As described above, in the present embodiment, similar to the second embodiment, the third microcomputer MP13 and the third power supply element PS3 are arranged along the parallel direction of the first microcomputer MP11 and the second microcomputer MP12. Therefore, there is no risk that the wiring (a conductor) connecting the third power supply element PS3 and the third microcomputer MP13 will straddle the first and second microcomputers MP11 and MP12. It is thus possible to suppress influence of noise that occurs when power supply from the third power supply element PS3 to the third microcomputer MP13 is done while straddling the first and second microcomputers MP11 and MP12.

Further, in the present embodiment, the third microcomputer MP13 and the third power supply element PS3 are located between the first and second microcomputers MP11 and MP12 and the first and second power supply elements PS1 and PS2.

Therefore, even if the third microcomputer MP13 and the third power supply element PS3 are not arranged along the parallel direction of the first microcomputer MP11 and the second microcomputer MP12, there is no risk that the wiring (a conductor) connecting the third power supply element PS3 and the third microcomputer MP13 will straddle the first and second microcomputers MP11 and MP12. It is thus possible to suppress influence of noise that occurs when power supply from the third power supply element PS3 to the third microcomputer MP13 is done while straddling the first and second microcomputers MP11 and MP12.

### Fourth Embodiment

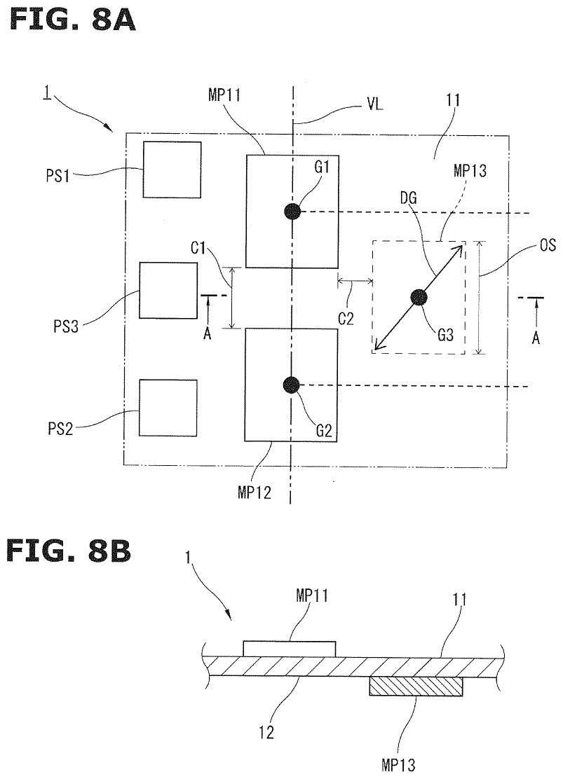

FIG. 8 illustrates a fourth embodiment of the drive control device according to the present invention. In the present embodiment, arrangement of the third power supply element PS3 and the third microcomputer MP13 of the first embodiment is changed, but the other configurations are the same as those of the first embodiment. Therefore, the same configurations are denoted by the same reference sign, and their detailed descriptions are omitted here.

### Configuration of Drive Control Device

FIGS. 8A and 8B are diagrams showing an essential part of the first drive control device DA1 according to the fourth embodiment of the present invention. FIG. 8A is a schematic diagram showing a positional relationship (layout) between the first and second microcomputers MP11 and MP12 and the first, second and third power supply elements PS1, PS2 and PS3 on the first mounting surface 11 of the circuit board 1. FIG. 8B is a sectional view taken along a line A-A of FIG. 8A.

As illustrated in FIGS. 8A and 8B, in the first drive control device DA1 according to the fourth embodiment, the circuit board 1 has the first mounting surface 11 provided on a front side shown in FIG. 8B, and a second mounting surface 12 provided on a back side. On the first mounting surface 11, two microcomputers of the first and second microcomputers MP11 and MP12, which constitute the main systems, and three power supply elements (power supply ICs) of first, second and third power supply elements PS1, PS2 and PS3, are mounted. Here, a positional relationship between the first and second microcomputers MP11 and MP12 and the first, second and third power supply elements PS1, PS2 and PS3 is the same as that of the first embodiment.

On the other hand, on the second mounting surface 12, the third microcomputer MP13, which constitutes the backup system when either the first microcomputer MP11 or the second microcomputer MP12 fails, is mounted. Similar to the first embodiment, the third microcomputer MP13 is arranged at a downstream side with respect to the first and second microcomputers MP11 and MP12, i.e. at a pre-driver (the first, second and third pre-drivers PD11, PD12 and PD13) side with respect to a virtual line VL connecting a center G1 of the first microcomputer MP11 and a center G2 of the second microcomputer MP12. Furthermore, the third microcomputer MP13 is arranged such that a part of the third microcomputer MP13 faces at least one of the first microcomputer MP11 and the second microcomputer MP12 across the circuit board 1 when viewed from a direction orthogonal to the virtual line VL in a horizontal direction of the circuit board 1.

Here, as illustrated in FIG. 8, it is desirable that a center G3 of the third microcomputer MP13 is located between the center G1 of the first microcomputer MP11 and the center G2 of the second microcomputer MP12 in a plan view of the circuit board 1. It is more desirable that the third microcomputer MP13 is arranged such that the center G3 of the third microcomputer MP13 is equidistant from the centers G1 and G2 of the first and second microcomputers MP11 and MP12.

### Working and Effect of the Present Embodiment

As described above, in the first drive control device DA1 according to the present embodiment, the circuit board 1 has the first mounting surface 11 provided on the front side, and the second mounting surface 12 provided on the back side. The first microcomputer MP11 is mounted on the first mounting surface 11, and the second microcomputer MP12 or the third microcomputer MP13 is mounted on the second mounting surface 12.

As described above, according to the present embodiment, the third microcomputer MP13 is disposed on the second mounting surface 12, which is an opposite side to the first mounting surface 11 on which the first microcomputer MP11 is mounted, of the circuit board 1. Therefore, a mounting area of the third microcomputer MP13 on the first mounting surface 11 of the circuit board 1 can be reduced by an area of the third microcomputer MP13 disposed on the second mounting surface 12. This allows reduction in size of the circuit board 1, which contributes to size reduction of the first drive control device DA1.

Furthermore, in the present embodiment, the third microcomputer MP13 disposed on the second mounting surface 12 is arranged such that a part of the third microcomputer MP13 deviates in a planar direction of the circuit board 1 with respect to the first microcomputer MP11 disposed on the first mounting surface 11.

As described above, in the present embodiment, the third microcomputer MP13 is arranged such that at least a part of the third microcomputer MP13 disposed on the second mounting surface 12 deviates in a planar direction of the circuit board 1 with respect to the first and second microcomputers MP11 and MP12 disposed on the first mounting surface 11. In other words, the third microcomputer MP13 is arranged so as not to completely overlap the first and second microcomputers MP11 and MP12 in the planar direction of the circuit board 1. With this arrangement, there is no risk that the wiring (a conductor) connecting to the third microcomputer MP13 and the wiring (a conductor) connecting to the first microcomputer MP11 will completely overlap each other, thereby improving the layout flexibility of the wiring (conductors) connecting to each of the first, second and third microcomputers MP11, MP12 and MP13.

Especially in the present embodiment, the third microcomputer MP13 is arranged so as to completely deviate with respect to the first and second microcomputers MP11 and MP12 in the planar direction of the circuit board 1. Therefore, it is possible to maximize the improvement in the layout flexibility of the wiring (conductors) connecting to each of the first, second and third microcomputers MP11, MP12 and MP13.

### Modified Example

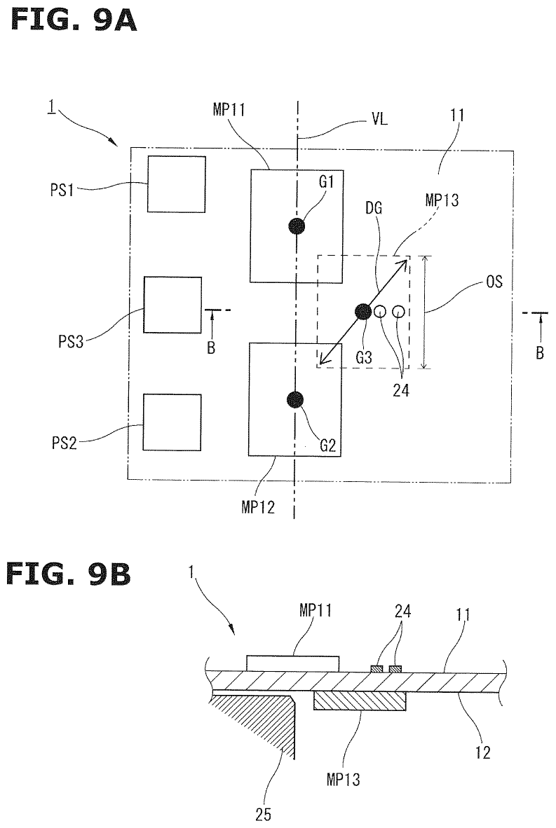

FIGS. 9A and 9B are a modified example of the fourth embodiment of the drive control device according to the present invention, and show a positional relationship (layout) between the first, second and third microcomputers MP11, MP12 and MP13 and the first, second and third power supply elements PS1, PS2 and PS3 on the first mounting surface 11 of the circuit board 1. More specifically, FIG. 9A is a schematic diagram of a plan view of the first mounting surface 11 of the circuit board 1. FIG. 9B is a sectional view taken along a line B-B of FIG. 9A.

As illustrated in FIGS. 9A and 9B, in the first drive control device DA1 according to the present modified example, on the second mounting surface 12, which is an opposite side to the first mounting surface 11 on which the first and second microcomputers MP11 and MP12 are mounted, a heat sink 25 as a heat dissipation member for dissipating heat of the first and second microcomputers MP11 and MP12 is disposed at a position (in an area) that overlaps the first and second microcomputers MP11 and MP12 across the circuit board 1.

In addition, on the second mounting surface 12 of the circuit board 1, the third microcomputer MP13 is arranged such that a part of the third microcomputer MP13 overlaps the first and second microcomputers MP11 and MP12 (see a broken line in FIG. 9A) across the circuit board 1. In other words, the third microcomputer MP13 is arranged such that a part of the third microcomputer MP13 overlaps (faces), across the circuit board 1, lower and upper portions of the first and second microcomputers MP11 and MP12 respectively in a longitudinal direction of the circuit board 1.

On the other hand, on the first mounting surface 11, which is an opposite side to the second mount ing surface 12 on which the third microcomputer MP13 is mounted, electrolytic capacitors 24 as noise removal components for removing noise of the third microcomputer MP13 are disposed at a position (in an area) that overlaps the third microcomputer MP13 across the circuit board 1.

As described above, in the first drive control device DA1 according to the present modified example, on the other mounting surface, which is an opposite side to one mounting surface on which at least one of the first, second and third microcomputers MP11, MP12 and MP13 is arranged, a heat dissipation member for dissipating heat of the microcomputer arranged on the one mounting surface, or a noise removal component for removing noise of the microcomputer arranged on the one mounting surface, is disposed.

As described above, according to the present modified example, on the second mounting surface 12 of the circuit board 1, the heat sink 25 as the heat dissipation member for dissipating heat of the first and second microcomputers MP11 and MP12 mounted on the first mounting surface 11 is disposed. With this, heat generated in the first and second microcomputers MP11 and MP12 can be effectively dissipated. On the other hand, on the first mounting surface 11 of the circuit board 1, the electrolytic capacitors 24 as noise removal components for removing noise of the third microcomputer MP13 mounted on the second mounting surface 12 are disposed. With this, electromagnetic noise generated in the third microcomputer MP13 can be effectively removed.

Furthermore, in the present modified example, on the second mounting surface 12, the third microcomputer MP13 is arranged such that a part of the third microcomputer MP13 overlaps the first and second microcomputers MP11 and MP12 across the circuit board 1. With this, a planar area of the circuit board 1 which his occupied by the third microcomputer MP13, particularly a longitudinal dimension of the circuit board 1, is reduced by an area where the third microcomputer MP13 overlaps the first and second microcomputers MP11 and MP12, thereby reducing the size of the circuit board 1. This contributes to size reduction of the first drive control device DA1.

The present invention is not limited to the configurations or structures disclosed in the above embodiments etc. The present invention can be freely changed according to, for instance, specification etc. of the drive control device to which the present invention is applied.

In particular, the feature of the present invention lies in arrangement (layout) of the first, second and third microcomputers MP11, MP12 and MP13 and the first, second and third power supply elements PS1, PS2 and PS3. Therefore, detailed configurations or structures which are not directly related to the feature of the present invention, for instance, specific structure including configuration of the circuit board 1 such as the number of the circuit boards, or peripheral electronic components mounted on the circuit board 1, can be freely changed according to, for instance, specification etc. of the drive control device to which the present invention is applied.

In addition, each of the above embodiments exemplifies a case in which the present invention is applied to the triplex redundant system. However, as long as the present invention has at least three or more microcomputers and power supply ICs, the present invention can be applied to quadruple redundant system.

1. A drive control device comprising
at least three drive systems each supplying driving power to a winding of an electric motor, wherein
a first drive system, a second drive system, and a third drive system, which constitute the three drive systems, include, on a circuit board, a first microcomputer, a second microcomputer, and a third microcomputer respectively, which are rectangular in shape in a plan view of the circuit board,
the first drive system is driven and controlled by the first microcomputer,
the second drive system is driven and controlled by the second microcomputer,
the third drive system is driven and controlled by the third microcomputer,
the first microcomputer, and the second microcomputer are arranged closer than a dimension of one side or a diagonal line of an outline of the third microcomputer in the plan view of the circuit board, and
the third microcomputer is arranged such that
a center of the third microcomputer is located at one side with respect to a virtual line connecting a center of the first microcomputer and a center of the second microcomputer, and
at least a part of the third microcomputer overlaps at least one of the first microcomputer and the second microcomputer when viewed from a direction orthogonal to the virtual line in a horizontal direction of the circuit board.

2. The drive control device as claimed in claim 1, wherein
the first drive system, and the second drive system are main systems that mainly drive and control the electric motor, and
the third drive system is a backup system that functions as an alternative to the first drive system or the second drive system when the first drive system or the second drive system fails.

3. The drive control device as claimed in claim 2, wherein
the third microcomputer is located apart from the first microcomputer and the second microcomputer with a distance that is greater than a distance between the first microcomputer and the second microcomputer and that is smaller than the dimension of the one side or the diagonal line of the outline of the third microcomputer.

4. The drive control device as claimed in claim 1, wherein
the first drive system includes a first power supply element that supplies power to the first microcomputer, and a first pre-driver that drives the electric motor based on a control signal from the first microcomputer,
the second drive system includes a second power supply element that supplies power to the second microcomputer, and a second pre-driver that drives the electric motor based on a control signal from the second microcomputer,
the third drive system includes a third power supply element that supplies power to the third microcomputer, and a third pre-driver that drives the electric motor based on a control signal from the third microcomputer,
the electric motor is driven by each of the pre-drivers, based on the control signal from the first microcomputer, the second microcomputer, or the third microcomputer,
the first pre-driver, the second pre-driver, and the third pre-driver are arranged at an opposite side to the first microcomputer and the second microcomputer with respect to the third microcomputer,
the first power supply element, and the second power supply element are arranged at an opposite side to the pre-drivers with respect to the first microcomputer and the second microcomputer, and
the third microcomputer, and the third power supply element are arranged along a parallel direction of the first microcomputer and the second microcomputer.

5. The drive control device as claimed in claim 4, wherein
the third microcomputer, and the third power supply element are arranged at a pre-driver side with respect to the first microcomputer and the second microcomputer.

6. The drive control device as claimed in claim 4, wherein
the third microcomputer, and the third power supply element are arranged between the first and second microcomputers and the first and second power supply elements.

7. The drive control device as claimed in claim 1, wherein
the third microcomputer is arranged such that the center of the third microcomputer is located between the center of the first microcomputer and the center of the second microcomputer when viewed from the direction orthogonal to the virtual line in the horizontal direction of the circuit board.

8. The drive control device as claimed in claim 7, wherein
the first microcomputer, the second microcomputer, and the third microcomputer are arranged at equal distances from each other.

9. The drive control device as claimed in claim 1, wherein
the circuit board has a first mounting surface provided on a front side of the circuit board, and a second mounting surface provided on a back side of the circuit board,
the first microcomputer is mounted on the first mounting surface, and
the second microcomputer or the third microcomputer is mounted on the second mounting surface.

10. The drive control device as claimed in claim 9, wherein
the second microcomputer or the third microcomputer disposed on the second mounting surface is arranged such that a part of the second microcomputer or a part of the third microcomputer deviates in a planar direction of the circuit board with respect to the first microcomputer disposed on the first mounting surface.

11. The drive control device as claimed in claim 10, wherein
on the other mounting surface, which is an opposite side to one mounting surface on which at least one of the first, second, and third microcomputers is arranged, a heat dissipation member for dissipating heat of the microcomputer arranged on the one mounting surface, or a noise removal component for removing noise of the microcomputer arranged on the one mounting surface, is disposed.

12. The drive control device as claimed in claim 11, wherein
the first drive system, and the second drive system are main systems that mainly drive and control the electric motor,
the third drive system is a backup system that functions as an alternative to the first drive system or the second drive system when the first drive system or the second drive system fails, and
the second microcomputer or the third microcomputer disposed on the second mounting surface is a microcomputer of the backup system.
